(19) United States
(12) Patent Application Publication
(10) Pub. No.: US 2024/0425967 A1
(43) Pub. Date: Dec. 26, 2024

(54) FAR-INFRARED TRANSMITTING MEMBER AND METHOD OF MANUFACTURING FAR-INFRARED TRANSMITTING MEMBER

(71) Applicant: AGC Inc., Tokyo (JP)

(72) Inventors: Hidehisa INOUE, Tokyo (JP); Yoji YASUI, Tokyo (JP)

(73) Assignee: AGC Inc., Tokyo (JP)

(21) Appl. No.: 18/823,833

(22) Filed: Sep. 4, 2024

Related U.S. Application Data
(63) Continuation of application No. PCT/JP2023/005653, filed on Feb. 17, 2023.

(30) Foreign Application Priority Data
Mar. 7, 2022 (JP) 2022-034675

(51) Int. Cl. C23C 14/08; B60J 1/02; B60J 1/20; C23C 14/00; C23C 14/35

(52) U.S. Cl. CPC C23C 14/085; B60J 1/02; B60J 1/2094; C23C 14/0036; C23C 14/35

(57) ABSTRACT

To appropriately transmit a far infrared ray and improve scratch resistance. A far-infrared transmitting member 20 includes a substrate 30 that transmits a far infrared ray and a first functional film 32 that is formed on the substrate 30 and includes a NiOₓ layer 34 containing NiOₓ as a main component, an average transmittance of light having a wavelength of 8 μm to 12 μm is 50% or more, and a maximum value Hₘₐₓ of indentation hardness in a range of an indentation depth of 40 nm or more and 110 nm or less from the surface of the functional film measured by a nanoindentation method is 10 GPa or more.

### FIELD

The present invention relates to a far-infrared transmitting member and a method of manufacturing the far-infrared transmitting member.

### BACKGROUND

For example, when a far-infrared sensor is attached to a vehicle or the like, in some case, a far-infrared transmitting member formed with a functional film for allowing a far infrared ray to be appropriately made incident on the far-infrared sensor is provided. For example, Patent Literature 1 describes that an infrared transmitting film containing zinc oxide as a main component and containing a metal oxide is formed on a substrate. Further, for example, Non-Patent Literature 1 describes that a nickel oxide film is formed as a far-infrared transmitting film on a Si substrate.

It is important that a far-infrared transmitting film for increasing a transmission light amount of a far infrared ray has high scratch resistance. However, according to Non Patent Literature 1, for example, the indentation hardness of a nickel oxide film formed on a Si substrate by an RF magnetron sputtering method is as low as 6.1 GPa. Therefore, it is expected that scratches are likely to occur.

### CITATION LIST

### Non Patent Literature

Non Patent Literature 1: Hyun Bin Shim et al., Controlling the infrared optical properties of rf-sputtered NiO films for application of infrared window, Infrared Physics and Technology 72 (2015), 135-139

### Patent Literature

Patent Literature 1: JP 2017-151408 A

### SUMMARY

### Technical Problem

Such a far-infrared transmitting member is required to improve scratch resistance while appropriately transmitting a far infrared ray.

An object of the present invention is to provide a far-infrared transmitting member capable of appropriately transmitting a far infrared ray and improving scratch resistance and a method of manufacturing the far-infrared transmitting member.

### Solution to Problem

The far-infrared transmitting member comprises: a substrate that transmits a far infrared ray; and a functional film formed on the substrate and including one or more NiOₓ layers containing NiOₓ as a main component, wherein an average transmittance of light having a wavelength of 8 μm to 12 μm is 50% or more, and a maximum value Hₘₐₓ of indentation hardness in a range of an indentation depth of 40 nm or more and 110 nm or less from a surface of the functional film measured by a nanoindentation method is 10 GPa or more.

The method of manufacturing a far-infrared transmitting member comprises: forming a NiOₓ layer containing NiOₓ as a main component on a substrate that transmits a far infrared ray with a post-oxidation sputtering method to manufacture the far-infrared transmitting member.

### Advantageous Effects of Invention

According to the present invention, it is possible to appropriately transmit a far infrared ray and improve scratch resistance.

### BRIEF DESCRIPTION OF DRAWINGS

FIG. 1 is a schematic diagram illustrating a state in which a vehicle glass according to the present embodiment is mounted on a vehicle.

FIG. 2 is a schematic plan view of the vehicle glass according to the present embodiment.

FIG. 3 is a cross-sectional view taken along an A-A line in FIG. 2.

FIG. 4 is a cross-sectional view taken along a B-B cross section in FIG. 2.

FIG. 5 is a schematic cross-sectional view of a far-infrared transmitting member according to the present embodiment.

FIG. 6 is a schematic view for explaining a method of manufacturing the far-infrared transmitting member according to the present embodiment.

FIG. 7 is a schematic cross-sectional view of a far-infrared transmitting member according to another example of the present embodiment.

### DESCRIPTION OF EMBODIMENTS

A preferred embodiment of the present invention is explained in detail below with reference to the accompanying drawings. Note that the present invention is not limited by the embodiment. When there are a plurality of embodiments, the present invention includes a combination of the embodiments. A numerical value includes a range of rounding.

### (Vehicle)

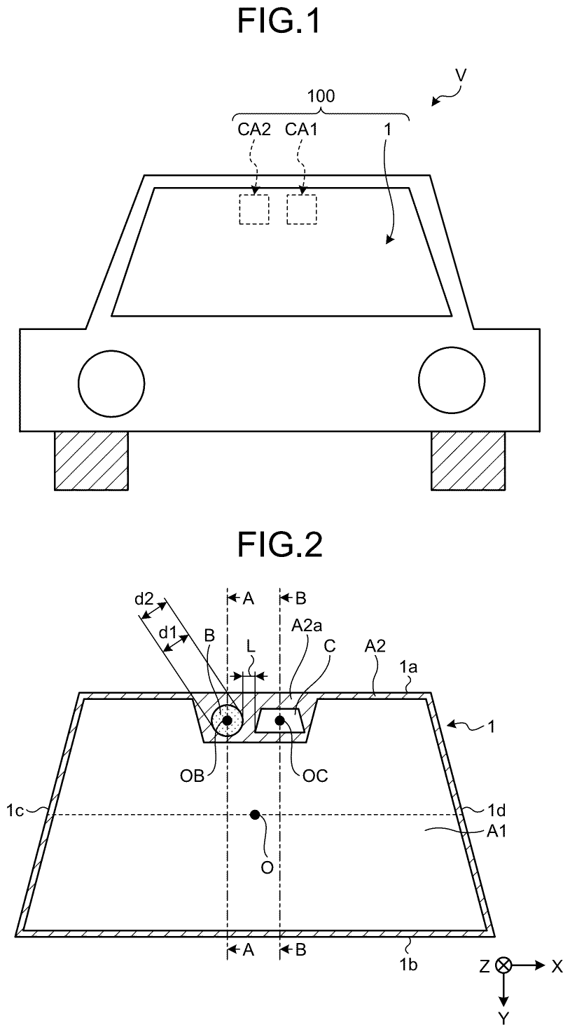

FIG. 1 is a schematic diagram illustrating a state in which a vehicle glass according to the present embodiment is mounted on a vehicle. As illustrated in FIG. 1, a vehicle glass 1 according to the present embodiment is mounted on a vehicle V. The vehicle glass 1 is a window member applied to a windshield of the vehicle V. That is, the vehicle glass 1 is used as a windshield of the vehicle V, in other words, windshield glass. A far-infrared camera CA1 and a visible light camera CA2 are mounted the inside (an interior) of the vehicle V. Note that the inside (the interior) of the vehicle V indicates, for example, a vehicle interior in which a driver's seat of a driver is provided.

The vehicle glass 1, the far-infrared camera CA1, and the visible light camera CA2 configure a camera unit 100 according to the present embodiment. The far-infrared camera CA1 is a camera that detects a far infrared ray. The far-infrared camera CA1 detects a far infrared ray from the outside of the vehicle V to capture a thermal image of the outside of the vehicle V. The visible light camera CA2 is a camera that detects visible light. The visible light camera CA2 detects visible light from the outside of the vehicle V to capture an image of the outside of the vehicle V. Note that the camera unit 100 may further include, for example, a LiDAR or a millimeter wave radar besides the far-infrared camera CA1 and the visible light camera CA2. Here, the far infrared ray is, for example, an electromagnetic wave having a wavelength in a wavelength band of 8 μm to 13 μm. The visible light is, for example, an electromagnetic wave having a wavelength in a wavelength band of 360 nm to 830 nm. Here, 8 μm to 13 μm and 360 nm to 830 nm indicate 8 μm or more and 13 μm or less and 360 nm or more and 830 nm or less. The same applies below. Note that the far infrared ray may be an electromagnetic wave having a wavelength in a wavelength band of 8 μm to 12 μm.

### (Vehicle Glass)

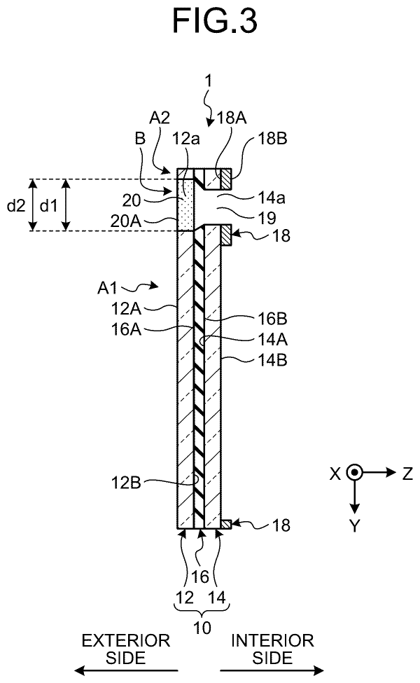

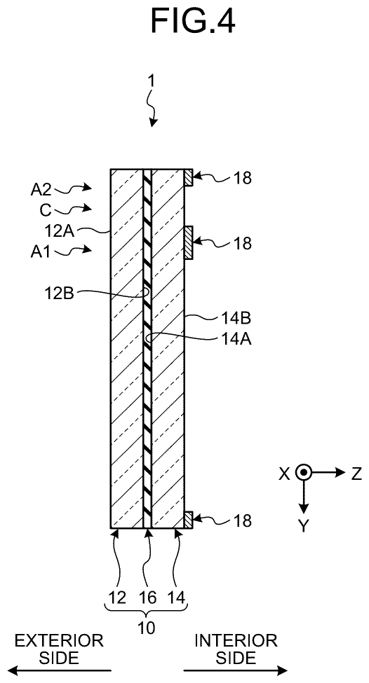

FIG. 2 is a schematic plan view of the vehicle glass according to the present embodiment. FIG. 3 is a cross-sectional view taken along an A-A line in FIG. 2. FIG. 4 is a cross-sectional view taken along a B-B cross section in FIG. 2. As illustrated in FIG. 2, in the following explanation, the upper edge of the vehicle glass 1 is referred to as upper edge 1a, the lower edge of the vehicle glass 1 is referred to as lower edge 1b, one side edge of the vehicle glass 1 is referred to as side edge 1c, and the other side edge of the vehicle glass 1 is referred to as side edge 1d. The upper edge 1a is an edge portion located on the vertically upper side when the vehicle glass 1 is mounted on the vehicle V. The lower edge 1b is an edge portion located on the lower side in the vertical direction when the vehicle glass 1 is mounted on the vehicle V. The side edge 1c is an edge portion located on one side when the vehicle glass 1 is mounted on the vehicle V. The side edge 1d is an edge portion located on the other side when the vehicle glass 1 is mounted on the vehicle V.

In the following explanation, among directions parallel to the surface of the vehicle glass 1, a direction from the upper edge 1a toward the lower edge 1b is referred to as Y direction and a direction from the side edge 1c toward the side edge 1d is referred to as X direction. In the present embodiment, the X direction and the Y direction are orthogonal. A direction orthogonal to the surface of the vehicle glass 1, that is, the thickness direction of the vehicle glass 1 is referred to as Z direction. The Z direction is, for example, a direction from the exterior side of the vehicle V toward the interior side of the vehicle V when the vehicle glass 1 is mounted on the vehicle V. The X direction and the Y direction are along the surface of the vehicle glass 1 but may be directions in contact with the surface of the vehicle glass 1 at a center point O of the vehicle glass 1, for example, when the surface of the vehicle glass 1 is a curved surface. The center point O is the center position of the vehicle glass 1 in the case in which the vehicle glass 1 is viewed from the Z direction.

A light transmitting region A1 and a light blocking region A2 are formed in the vehicle glass 1. The light transmitting region A1 is a region occupying the central portion of the vehicle glass 1 when viewed from the Z direction. The light transmitting region A1 is a region for securing the visual field of a driver. The light transmitting region A1 is a region that transmits visible light. The light blocking region A2 is a region formed around the light transmitting region A1 when viewed from the Z direction. The light blocking region A2 is a region that blocks visible light. In the light blocking region A2, a far-infrared transmitting region B and a visible light transmitting region C are formed in a light blocking region A2a, which is a portion on the upper edge 1a side.

The far-infrared transmitting region B is a region that transmits a far infrared ray and is a region where the far-infrared camera CA1 is provided. That is, the far-infrared camera CA1 is provided at a position overlapping the far-infrared transmitting region B when viewed from the optical axis direction of the far-infrared camera CA1. The visible light transmitting region C is a region that transmits visible light and is a region where the visible light camera CA2 is provided. That is, the visible light camera CA2 is provided at a position overlapping the visible light transmitting region C when viewed from the optical axis direction of the visible light camera CA2.

As explained above, since the far-infrared transmitting region B and the visible light transmitting region C are formed in the light blocking region A2, the light blocking region A2 blocks a far infrared ray in a region other than a region where the far-infrared transmitting region B is formed and blocks visible light in a region other than the region where the visible light transmitting region C is formed. The light blocking region A2a is formed around the far-infrared transmitting region B and the visible light transmitting region C. The light blocking region A2a is preferably provided around the far-infrared transmitting region B and the visible light transmitting region C as explained above because various sensors are protected from sunlight. Wiring of the various sensors is preferably invisible from the outside of the vehicle from the viewpoint of designability.

As illustrated in FIG. 3, the vehicle glass 1 includes a glass substrate 12 (a first glass substrate), a glass substrate 14 (a second glass substrate), an intermediate layer 16, and a light blocking layer 18. In the vehicle glass 1, the glass substrate 12, the intermediate layer 16, the glass substrate 14, and the light blocking layer 18 are laminated in this order in the Z direction. The glass substrate 12 and the glass substrate 14 are fixed (bonded) to each other with the intermediate layer 16 interposed therebetween.

As the glass substrates 12 and 14, for example, soda-lime glass, borosilicate glass, aluminosilicate glass, or the like can be used. The intermediate layer 16 is an adhesive layer that bonds the glass substrate 12 and the glass substrate 14. As the intermediate layer 16, for example, a polyvinyl butyral (hereinafter also referred to as PVB) modified material, an ethylene-vinyl acetate copolymer (EVA)-based material, a urethane resin material, or a vinyl chloride resin material can be used. More specifically, the glass substrate 12 includes one surface 12A and the other surface 12B. The other surface 12B is in contact with one surface 16A of the intermediate layer 16 and fixed (bonded) to the intermediate layer 16. The glass substrate 14 includes one surface 14A and the other surface 14B. The one surface 14A is in contact with the other surface 16B of the intermediate layer 16 and fixed (bonded) to the intermediate layer 16. As explained above, the vehicle glass 1 is a laminated glass obtained by laminating the glass substrate 12 and the glass substrate 14.

However, the vehicle glass 1 is not limited to the laminated glass and may be configured to include, for example, only one of the glass substrate 12 and the glass substrate 14. In this case, the intermediate layer 16 may not be provided either. In the following explanation, when the glass substrates 12 and 14 are not distinguished, the glass substrates 12 and 14 are described as glass substrate 10.

The light blocking layer 18 includes one surface 18A and the other surface 18B. The one surface 18A is fixed in contact with the other surface 14B of the glass substrate 14. The light blocking layer 18 is a layer that blocks visible light. As the light blocking layer 18, for example, a ceramic light blocking layer or a light blocking film can be used. As the ceramic light blocking layer, for example, a ceramic layer made of a material publicly known in the past such as a black ceramic layer can be used. As the light blocking film, for example, a light blocking polyethylene terephthalate (PET) film, a light blocking polyethylene naphthalate (PEN) film, or a light blocking polymethyl methacrylate (PMMA) film can be used.

In the present embodiment, in the vehicle glass 1, a side on which the light blocking layer 18 is provided is the inner side (the interior side) of the vehicle V and a side on which the glass substrate 12 is provided is the outer side (the exterior side) of the vehicle V. However, not only this, but the light blocking layer 18 may be on the exterior side V. When the vehicle glass 1 is configured by the laminated glass of the glass substrates 12 and 14, the light blocking layer 18 may be formed between the glass substrate 12 and the glass substrate 14.

### (Light Blocking Region)

The light blocking region A2 is formed by providing the light blocking layer 18 on the glass substrate 10. That is, the light blocking region A2 is a region where the glass substrate 10 includes the light blocking layer 18. That is, the light blocking region A2 is a region where the glass substrate 12, the intermediate layer 16, the glass substrate 14, and the light blocking layer 18 are laminated. On the other hand, the light transmitting region A1 is a region where the glass substrate 10 does not include the light blocking layer 18. That is, the light transmitting region A1 is a region where the glass substrate 12, the intermediate layer 16, and the glass substrate 14 are laminated and the light blocking layer 18 is not laminated.

### (Far-Infrared Transmitting Region)

As illustrated in FIG. 3, in the vehicle glass 1, an opening 19 penetrating from one surface (here, the surface 12A) to the other surface (here, the surface 14B) in the Z direction is formed. A far-infrared transmitting member 20 is provided in the opening 19. A region where the opening 19 is formed and the far-infrared transmitting member 20 is provided is the far-infrared transmitting region B. That is, the far-infrared transmitting region B is a region where the opening 19 and the far-infrared transmitting member 20 disposed in the opening 19 are provided. Since the light blocking layer 18 does not transmit a far infrared ray, the light blocking layer 18 is not provided in the far-infrared transmitting region B. That is, in the far-infrared transmitting region B, the glass substrate 12, the intermediate layer 16, the glass substrate 14, and the light blocking layer 18 are not provided and the far-infrared transmitting member 20 is provided in the formed opening 19. The far-infrared transmitting member 20 is explained below.

### (Visible Light Region)

As illustrated in FIG. 4, like the light transmitting region A1, the visible light transmitting region C is a region where the glass substrate 10 does not include the light blocking layer 18 in the Z direction. That is, the visible light transmitting region C is a region where the glass substrate 12, the intermediate layer 16, and the glass substrate 14 are laminated and the light blocking layer 18 is not laminated.

As illustrated in FIG. 2, the visible light transmitting region C is preferably provided in the vicinity of the far-infrared transmitting region B. Specifically, the center of the far-infrared transmitting region B viewed from the Z direction is referred to as center point OB and the center of the visible light transmitting region C viewed from the Z direction is referred to as center point OC. When the shortest distance between the far-infrared transmitting region B (the opening 19) and the visible light transmitting region C when viewed from the Z direction is referred to as distance L, the distance L is preferably more than 0 mm and 100 mm or less and more preferably 10 mm or more and 80 mm or less. By setting the visible light transmitting region C to a position within this range with respect to the far-infrared transmitting region B, it is possible to appropriately capture an image with the visible light camera CA2 with a perspective distortion amount in the visible light transmitting region C suppressed while making it possible to capture an image at a close position with the far-infrared camera CA1 and the visible light camera CA2. By capturing the image at the close position close with the far-infrared camera CA1 and the visible light camera CA2, a load in performing arithmetic processing on data obtained from the respective cameras is reduced and a power supply and a signal cable are also suitably laid.

As illustrated in FIG. 2, the visible light transmitting region C and the far-infrared transmitting region B are preferably located side by side in the X direction. That is, it is preferable that the visible light transmitting region C is not located on the Y direction side of the far-infrared transmitting region B and is located side by side with the far-infrared transmitting region B in the X direction. By disposing the visible light transmitting region C side by side with the far-infrared transmitting region B in the X direction, it is possible to dispose the visible light transmitting region C in the vicinity of the upper edge 1a. Therefore, it is possible to appropriately secure the visual field of the driver in the light transmitting region A1.

### (Far-Infrared Transmitting Member)

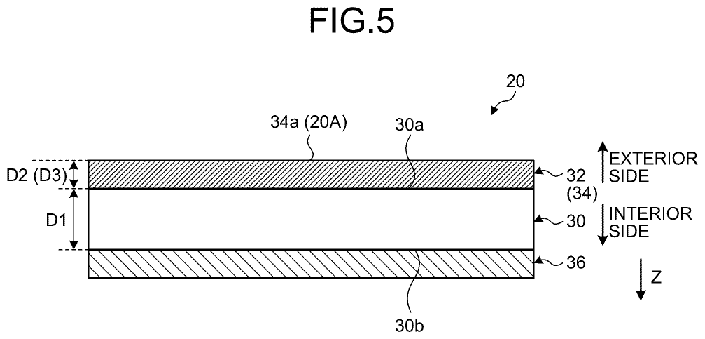

In the following explanation, the far-infrared transmitting member 20 provided in the far-infrared transmitting region B is specifically explained. FIG. 5 is a schematic cross-sectional view of the far-infrared transmitting member according to the present embodiment. As illustrated in FIG. 5, the far-infrared transmitting member 20 includes a substrate 30, a first functional film 32 serving as a functional film formed on the substrate 30, and a second functional film 36 formed on the substrate 30. In the present embodiment, the first functional film 32 is formed on one surface 30a of the substrate 30. The surface 30a is a surface that is on the exterior side when the far-infrared transmitting member 20 is mounted on the vehicle glass 1. The second functional film 36 is formed on the other surface 30b of the substrate 30. The front surface 30b is a surface that is on the interior side when the far-infrared transmitting member 20 is mounted on the vehicle glass 1. However, the second functional film 36 is not an essential component. A layer other than the substrate 30 may not be provided on the surface 30b.

In the present embodiment, the far-infrared transmitting member 20 is provided in the light blocking region A2 of the vehicle glass 1, which is a window member of the vehicle V. However, not only this, but the far-infrared transmitting member 20 may be provided in any exterior member of the vehicle V such as an exterior member for a pillar of the vehicle V. That is, the far-infrared transmitting member 20 may be disposed in the window member of the vehicle, may be disposed in the exterior member for the pillar of the vehicle, or may be disposed in the light blocking region of the exterior member for the vehicle. The far-infrared transmitting member 20 is not limited to be provided in the vehicle V and may be used for any purpose.

### (Substrate)

The substrate 30 is a member capable of transmitting a far infrared ray. In the substrate 30, an internal transmittance with respect to light (a far infrared ray) having a wavelength of 10 μm is preferably 50% or more, more preferably 60% or more, still more preferably 70% or more. In the substrate 30, an average internal transmittance with respect to light (a far infrared ray) having a wavelength of 8 μm to 12 μm is preferably 50% or more, more preferably 60% or more, and still more preferably 70% or more. Since the internal transmittance of the substrate 30 at 10 μm and the average internal transmittance of the substrate 30 at 8 μm to 12 μm are within this numerical value range, it is possible to appropriate transmit a far infrared ray and sufficiently exert, for example, the performance of the far-infrared camera CA1. The average internal transmittance here is an average value of the internal transmittances of the wavelength band (here, 8 μm to 12 μm) with respect to the lights having the wavelengths.

The internal transmittance of the substrate 30 is a transmittance excluding surface reflection losses on an incident side and an emission side and is well known in the technical field. The internal transmittance may be measured by a method usually performed. The measurement is performed, for example, as explained below.

A pair of flat samples (a first sample and a second sample) made of the same composition substrate and having different thicknesses is prepared. Both surfaces of the flat sample are planes that are parallel to each other and are optically polished. When an external transmittance including a surface reflection loss of the first sample is represented as T1, an external transmittance including a surface reflection loss of the second sample is represented as T2, the thickness of the first sample is represented as Td1 (mm), and the thickness of the second sample is represented as Td2 (mm), where Td1<Td2, an internal transmittance τ at thickness Tdx (mm) can be calculated by the following Expression (1).

$$τ = exp [ - Tdx \times ( ln T 1 - ln T 2 ) / Δ Td ] \qquad ( 1 )$$

An external transmittance of an infrared ray can be measured by, for example, a Fourier transform infrared spectrometer (manufactured by ThermoScientific Inc.; product name: Nicolet iS10).

In the substrate 30, a refractive index with respect to light having a wavelength of 10 μm is preferably 1.5 or more and 4.0 or less, more preferably 2.0 or more and 4.0 or less, and still more preferably 2.2 or more and 3.5 or less. In the substrate 30, an average refractive index with respect to light having a wavelength of 8 μm to 12 μm is preferably 1.5 or more and 4.0 or less, more preferably 2.0 or more and 4.0 or less, and still more preferably 2.2 or more and 3.5 or less. Since the refractive index and the average refractive index of the substrate 30 are in this numerical value range, it is possible to appropriately transmit a far infrared ray and sufficiently exert, for example, the performance of the far-infrared camera CA1. Note that the average refractive index here is an average value of refractive indexes of the wavelength band (here, 8 μm to 12 μm) with respect to light having respective wavelengths. The refractive index can be determined by performing fitting of an optical model using, for example, polarization information obtained by an infrared spectroscopic ellipsometer (IR-VASE-UT manufactured by J. A. Woollam Co., Ltd.) and a spectral transmission spectrum obtained by a Fourier transform infrared spectrometer.

Thickness D1 of the substrate 30 is preferably 0.5 mm or more and 5 mm or less, more preferably 1 mm or more and 4 mm or less, and still more preferably 1.5 mm or more and 3 mm or less. Since the thickness D1 is in this range, it is possible to appropriately transmit a far infrared ray while securing strength. Note that the thickness D1 can also be considered length in the Z direction from the surface 30a to the surface 30b of the substrate 30.

The material of the substrate 30 is not particularly limited. Examples of the material include Si, Ge, ZnS, and chalcogenide glass. It can be said that the substrate 30 preferably contains at least one kind of material selected from a group of Si, Ge, ZnS, and chalcogenide glass. By using such a material for the substrate 30, a far infrared ray can be appropriately transmitted.

A preferred composition of the chalcogenide glass is a composition containing:
in atoms indication,
Ge+Ga; 7% to 25%,
Sb; 0% to 35%,
Bi; 0% to 20%,
Zn; 0% to 20%,
Sn; 0% to 20%,
Si; 0% to 20%,
La; 0% to 20%,
S+Se+Te; 55% to 80%,
Ti; 0.005% to 0.3%,
Li+Na+K+Cs; 0% to 20%, and
F+Cl+Br+I; 0% to 20%. The glass preferably has a glass transition point (Tg) of 140° C. to 550° C.

Note that Si or ZnS is more preferably used as the material of the substrate 30.

### (First Functional Film)

The first functional film 32 is formed on a surface 30a on the exterior side of the substrate 30. The first functional film 32 includes one or more NiOₓ layers 34. In the example illustrated in FIG. 5, the first functional film 32 includes only the NiOₓ layer 34 and does not include other layers. In the example illustrated in FIG. 5, the NiOₓ layer 34 is present on the outermost side (the side most distant from the substrate 30) in the first functional film 32.

However, the first functional film 32 is not limited to including only the NiOₓ layer 34 and may include other layers. As explained in detail below, the first functional film 32 may include another layer (an adhesion layer) further on the substrate 30 side than the NiOₓ layer 34. The first functional film 32 may include another layer (a hue adjustment layer or an outermost layer 39) further on the side opposite to the substrate 30 (the exterior side) than the NiOₓ layer 34. In this case, the NiOₓ layer 34 is not the outermost layer.

### (Nioₓ Layer)

The NiOₓ layer 34 is a layer containing NiOₓ as a main component. The main component here may indicate that a content with respect to the entire NiOₓ layer 34 is 50 mass % or more. In the NiOₓ layer 34, a content of NiOₓ is 50 mass % or more and 100 mass % or less, preferably 70 mass % or more and 100 mass % or less, and more preferably 90 mass % or more and 100 mass % or less with respect to the entire NiOₓ layer 34. Further, in of the NiOₓ layer 34, the content of a simple substance of NiOₓ that is, NiOₓ excluding an inevitable impurity is preferably 100 mass %. Since the content of NiOₓ is within this range, the NiOₓ layer 34 can appropriately transmit a far infrared ray and improve scratch resistance.

Note that it is known that nickel oxide takes a plurality of compositions according to the valence of nickel and x can take any value of 0.5 to 2. The valence may not be single and two or more kinds of valences may be mixed. In the present embodiment, NiO is preferably used as NiOₓ.

The NiOₓ layer 34 may contain an accessory component, which is a component other than NiOₓ serving as a main component. The accessory component is preferably an oxide that transmits a far infrared ray. Examples of the accessory component include at least one of ZrO₂, ZnO, Bi₂O₃, and CuOₓ.

Thickness D2 of the NiOₓ, layer 34 is preferably 300 nm or more and 2000 nm or less, more preferably 400 nm or more and 1500 nm or less, and still more preferably 1000 nm or more and 1300 nm or less. Note that the thickness D2 can also be considered length in the Z direction from the surface on the Z-direction side of the NiOₓ layer 34 to the surface on the side opposite to the Z direction.

A ratio of the thickness D2 of the NiOₓ layer 34 to the thickness D1 of the substrate 30 is preferably 0.02% or more and 0.4% or less, more preferably 0.02% or more and 0.3% or less, and still more preferably 0.03% or more and 0.08% or less.

A ratio of the thickness D2 of the NiOₓ layer 34 to thickness D3 of the first functional film 32 is more preferably 50% or more and 100% or less, still more preferably 60, or more and 100% or less, and still more preferably 70% or more and 100% or less. The thickness D3 of the first functional film 32 can also be considered length in the Z direction from the surface on the Z-direction side of the first functional film 32 to the surface on the side opposite to the Z direction.

Since the thickness D2 is in this range, it is possible to appropriately transmit a far infrared ray and appropriately improve scratch resistance.

The surface of the NiOₓ layer 34 on the side opposite to the substrate 30 is referred to as surface 34a. The surface 34a is a surface on a side exposed to the outside and can be considered a surface on the exterior side in the present embodiment. In this case, arithmetic average roughness Ra (surface roughness) of the surface 34a of the NiOₓ layer 34 is preferably 6 nm or less, more preferably 0.5 nm or more and 6 nm or less, still more preferably 0.5 nm or more and 5 nm or less, still more preferably 0.5 nm or more and 4 nm or less, and most preferably 0.5 nm or more and 3 nm or less. Since the arithmetic average roughness Ra of the surface 34a is in this range, it is possible to reduce the change in the coefficient of dynamic friction and the surface roughness before and after abrasion and more appropriately improve scratch resistance. The arithmetic average roughness Ra indicates the arithmetic average roughness Ra defined in JIS B 0601:2001.

Note that, here, the arithmetic average roughness Ra of the surface 34a of the NiOₓ layer 34 indicates a value in the case in which the NiOₓ layer 34 is the outermost layer (in the case in which the NiOₓ layer 34 is exposed to the outside). However, when another layer (the outermost layer 39) is formed further on the outer side than the NiOₓ layer 34 as explained below, the arithmetic average roughness Ra of a surface 39a of the outermost layer 39 may be the same value as the arithmetic average roughness Ra of the surface 34a of the NiOₓ layer 34 explained above.

The NiOₓ layer 34 can transmit a far infrared ray. In the NiOₓ layer 34, an extinction coefficient with respect to light having a wavelength of 10 μm is preferably 0.4 or less, more preferably 0.1 or less, still more preferably 0.05 or less, and still more preferably 0.04 or less. The extinction coefficient can be determined by performing fitting of an optical model using, for example, polarization information obtained by an infrared spectroscopic ellipsometer (IR-VASE-UT manufactured by J. A. Woollam Co., Ltd.) and a spectral transmission spectrum obtained by a Fourier transform infrared spectrometer.

In the NiOₓ layer 34, a refractive index with respect to light (visible light) having a wavelength of 550 nm is preferably 2.0 or more and 2.5 or less and more preferably 2.0 or more and 2.3 or less. Since the refractive index of the NiO; layer 34 with respect to visible light is in this numerical value range, it is possible to improve the denseness of the film of the NiOₓ layer 34 and more appropriately improve scratch resistance. The refractive index of light having a wavelength of 550 nm can be determined by performing fitting of an optical model using, for example, polarization information obtained by a spectroscopic ellipsometer (manufactured by J. A. Woollam, M-2000) and spectral transmittance measured based on JIS R3106.

In the NiOₓ layer 34, an extinction coefficient with respect to light (visible light) having a wavelength of 550 nm is preferably 0.04 or more, more preferably 0.06 or more, still more preferably 0.08 or more, and most preferably 0.10 or more. Since the extinction coefficient of the NiOₓ layer 34 with respect to visible light is in this numerical value range, it is possible to appropriately suppress reflectance dispersion of visible light and obtain an appearance that secures designability.

### (Second Functional Film)

The second functional film 36 provided on the surface 30b on the interior side of the substrate 30 is a layer that transmits a far infrared ray. The second functional film 36 may have the same configuration as the first functional film 32. That is, for example, in the far-infrared transmitting member 20, the substrate 30 and the NiOₓ layer 34 may be laminated in this order from the substrate 30 toward the interior side.

### (Characteristics of the Far-Infrared Transmitting Member)

As explained above, in the far-infrared transmitting member 20, the first functional film 32 including the NiOₓ layer 34 is formed on the surface 30a of the substrate 30. Since the NiOₓ layer 34 is formed, the far-infrared transmitting member 20 can appropriately improve the scratch resistance while appropriately transmitting the far infrared ray.

In the far-infrared transmitting member 20, a transmittance for light of 10 μm is preferably 50% or more, more preferably 65% or more, and still more preferably 70% or more. In the far-infrared transmitting member 20, an average transmittance with respect to light having a wavelength of 8 μm to 12 μm is preferably 50% or more, more preferably 65% or more, and still more preferably 70% or more. Since the transmittance and the average transmittance are in this range, it is possible to appropriately exert the function of the infrared transmitting member.

In the far-infrared transmitting member 20, a reflectance for light of 10 μm is preferably 15% or less, more preferably 10% or less, and still more preferably 5% or less. In the far-infrared transmitting member 20, an average reflectance with respect to light having a wavelength of 8 μm to 12 μm is preferably 15% or less, more preferably 10, or less, and still more preferably 5% or less. Since the reflectance and the average reflectance are in this range, it is possible to appropriately exert the function of the infrared transmitting member. Note that the average reflectance is an average value of reflectance with respect to lights having respective wavelengths in the wavelength band (here, 8 μm to 12 μm). The reflectance can be measured by, for example, a Fourier transform infrared spectrometer (Nicolet iS10 manufactured by ThermoScientific Inc.).

In the far-infrared transmitting member 20, the hardness of the surface 20A on the exterior side (in the example of FIG. 5, the surface 34a of the NiOₓ layer 34) is 10 GPa or more, preferably 12 GPa or more, further preferably 13 GPa or more, and most preferably 15 GPa or more. Since the hardness of the surface 20A is in this range, it is possible to appropriately improve scratch resistance.

The hardness of the surface 20A indicates indentation hardness in a range of an indentation depth of 40 nm or more and 110 nm or less measured by a nanoindentation method (a continuous stiffness measurement method) using a nanoindenter. More specifically, the indentation hardness is a value calculated from a displacement-load curve from loading to unloading of a measurement indenter and is defined in ISO 14577.

The indentation hardness can be measured as explained below. Specifically, using an iMicro nanoindenter manufactured by KLA Corporation, an indentation depth h (nm) corresponding to an indentation load P (mN) is continuously measured over an entire process from a start of loading to unloading at a measurement site and a P-h curve is created. Then, indentation hardness H (GPa) is calculated from the created P-h curve.

$$H = P / A \qquad ( 2 )$$

In Expression (2), P represents an indentation load (mN) and A represents a projection area (μm²) of the indenter.

In the present embodiment, a maximum value Hₘₐₓ of the indentation hardness H in a section where the indentation depth is 40 nm or more and 110 nm or less is set as the hardness of the surface 20A.

A Young's modulus E of the far-infrared transmitting member 20 is preferably 210 GPa or more and 300 GPa or less, more preferably 220 GPa or more and 300 GPa or less, and still more preferably 230 GPa or more and 300 GPa or less. A ratio Hₘₐₓ/E of the maximum value Hₘₐₓ of the indentation hardness H of the far-infrared transmitting member 20 and the Young's modulus E is preferably 0.045 or more and 0.120 or less, more preferably 0.050 or more and 0.120 or less, still more preferably 0.060 or more and 0.120 or less, and particularly preferably 0.070 or more and 0.120 or more. Both of the maximum value Hₘₐₓ and the Young's modulus E of the indentation hardness Hₘₐₓ/E of a surface 36a can be measured by the nanoindentation method. Since the Young's modulus E and the ratio Hₘₐₓ/E of the maximum value Hₘₐₓ of the indentation hardness H and the Young's modulus E of the far-infrared transmitting member 20 are in this range, a film is hardly broken and is easily restored. Therefore, the film is a film having strong scratch resistance and scratch resistance is improved.

In the far-infrared transmitting member 20, Δa*b* is preferably 5 or less, more preferably 4 or less, still more preferably 3 or less, particularly preferably 2 or less, and most preferably 1 or less. Δa*b* indicates the distance from an origin coordinate of a*b* in a CIE-Lab color system obtained from a 5-degree incident visible light reflection spectrum. That is, Δa*b* is calculated by the following Expression (3). Since Δa*b* is in this range, visible light reflected from the far-infrared transmitting member 20 has a neutral color and an appearance that secures designability can be obtained.

$$Δ {a}^{*} {b}^{⋆} = {( {a}^{* 2} + {b}^{* 2} )}^{0.5} \qquad ( 3 )$$

a*and b*are chromaticity coordinates of reflected light in the CIE-Lab color system at the time when a standard illuminant D65 is used for illumination light and can be calculated based on JIS Z 8781-4 using spectral reflectance measured based on JIS R3106.

In particular, when the far-infrared transmitting member 20 includes a NiOₓ film, an extinction coefficient of which in a visible region changes according to a degree of oxidation, it is possible to suppress a change in a* and b* involved in a change in the degree of oxidation of the NiOₓ film in a moisture resistance test, a water resistance test, or a heat resistance test.

As illustrated in FIG. 3, in the far-infrared transmitting member 20, the surface 20A on the exterior side is preferably formed to be flush with (continuous to) the surface on the exterior side of the light blocking region A2. In other words, the surface 20A of the far-infrared transmitting member 20 on the exterior side is attached so as to be continuous with the surface 12A of the glass substrate 12. Since the surface 20A of the far-infrared transmitting member 20 is continuous to the surface 12A of the glass substrate 12 as explained above, it is possible to suppress a wiping effect of a wiper from being impaired. It is possible to suppress likelihood of designability of the vehicle V being impaired because of the presence of a step or dust or the like accumulating on the step. Further, the far-infrared transmitting member 20 is preferably molded to be adjusted to a curved surface shape of the vehicle glass 1 to be applied. A method for molding the far-infrared transmitting member 20 is not particularly limited. Polishing or molding is selected according to a curved surface shape or a member.

The shape of the far-infrared transmitting member 20 is not particularly limited but is preferably a plate-like shape adjusted to the shape of the opening 19. That is, for example, when the opening 19 is circular, the far-infrared transmitting member 20 preferably has a disk shape (a columnar shape). From the viewpoint of designability, the surface shape of the far-infrared transmitting member 20 on the exterior side may be processed to match the curvature of the outer surface shape of the glass substrate 12. Further, the far-infrared transmitting member 20 may be formed in a lens shape for the reason of achieving both of widening of the viewing angle of the far-infrared camera CA1 and improvement of mechanical characteristics. Such a configuration is preferable because far-infrared light can be efficiently condensed even if the area of the far-infrared transmitting member 20 is small. In this case, the number of lens-shaped far-infrared transmitting members 20 is preferably one to three and is typically preferably two. Further, it is particularly preferable that the lens-shaped far-infrared transmitting member 20 is aligned in advance and modularized and is integrated with a housing or a bracket for bonding the far-infrared camera CA1 to the vehicle glass 1.

In the vehicle glass 1 of the present embodiment, it is preferable that the area of the opening 19 on the surface on the interior side is smaller than the area of the opening 19 on the surface on the exterior side and, accordingly, the area of the shape of the far-infrared transmitting member 20 on the surface on the interior side is preferably also set smaller than the area of the surface on the exterior side. With such a configuration, strength against impact from the exterior side is improved. Furthermore, when the vehicle glass 1 in the present embodiment is the laminated glass including the glass substrate 12 (the exterior side) and the glass substrate 14 (the interior side), the opening 19 is formed with the opening 12a of the glass substrate 12 and the opening 14a of the glass substrate 14 overlapping. In this case, the area of the opening 12a of the glass substrate 12 may be set larger than the area of the opening 14a of the glass substrate 14. The far-infrared transmitting member 20 adjusted to the size of the opening 12a of the glass substrate 12 only has to be disposed in the opening 12a of the glass substrate 12.

As illustrated in FIG. 3, in the far-infrared transmitting member 20, length d1 of a longest straight line among straight lines connecting any two points in the plane on the exterior side is preferably 80 mm or less. The length d1 is more preferably 70 mm or less and still more preferably 65 mm or less. The length d1 is preferably 60 mm or more. As illustrated in FIG. 3, length d2 of a longest straight line among straight lines connecting any two points in the plane on the exterior side of the opening 19 of the far-infrared transmitting region B is preferably 80 mm or less. The length d2 is more preferably 70 mm or less and still more preferably 65 mm or less. The length d2 is preferably 60 mm or more. The length d2 can also be considered the length of the longest straight line among the straight lines connecting any two points on the outer periphery of the opening 19 on the surface (the surface 12A) on the exterior side of the vehicle glass 1. By setting the length d1 of the far-infrared transmitting member 20 and the length d2 of the opening 19 in this range, it is possible to suppress a decrease in the strength of the vehicle glass 1 and also suppress an amount of perspective distortion around the opening 19. Note that, when the shape of the surface on the exterior side of the far-infrared transmitting member 20 is circular, the lengths d1 and d2 are lengths corresponding to the diameter of the surface on the exterior side. The lengths d1 and d2 here indicate lengths in a state in which the vehicle glass 1 is mounted on the vehicle V. For example, when glass is bent into a shape to be mounted on the vehicle V, the lengths d1 and d2 are lengths in a state after the bending is performed. The same applies to explanation of dimensions and positions other than the lengths d1 and d2 unless particularly explained otherwise.

### (Method of Manufacturing the Infrared Transmitting Member)

Subsequently, a method of manufacturing the far-infrared transmitting member 20 is explained. In the present embodiment, the far-infrared transmitting member 20 is manufactured by forming the NiOₓ layer 34 on the substrate 30 by a post-oxidation sputtering method. In the following explanation, a method of manufacturing the far-infrared transmitting member 20 is specifically explained. However, the far-infrared transmitting member 20 may be manufactured by any manufacturing method to have the characteristics explained above.

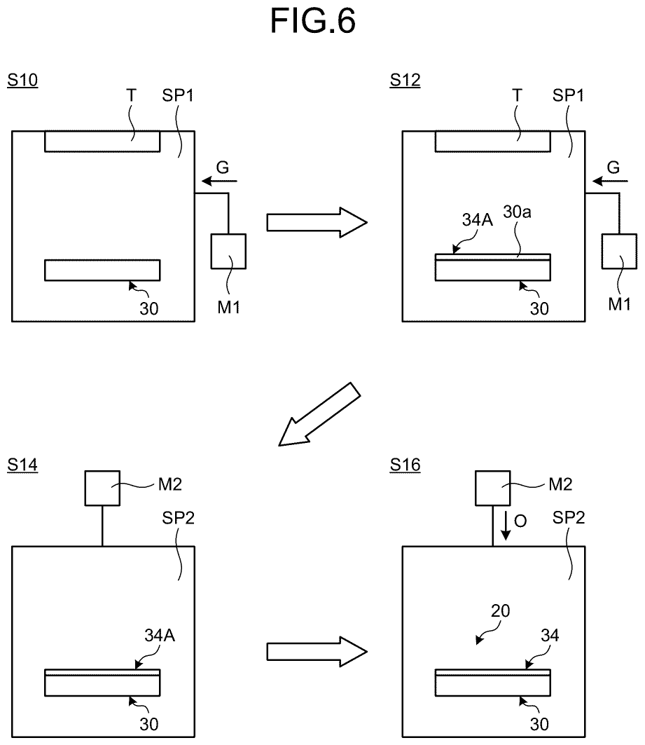

FIG. 6 is a schematic diagram illustrating a method of manufacturing the far-infrared transmitting member according to the present embodiment. As illustrated in FIG. 6, in the present manufacturing method, the substrate 30 is disposed in a first space SP1 (Step S10). A target T is provided in the first space SP1 and is connected to an inert gas supply unit M1. The target T is a member serving as a material of the NiOₓ layer 34 laminated on the substrate 30. The substrate 30 is disposed in the first space SP1 such that the surface 30a on the side where the NiOₓ layer 34 is formed faces the target T. The inert gas supply unit M1 is a device that supplies an inert gas G into the first space SP1 and changes the first space SP1 to an inert gas G atmosphere. As the inert gas G, argon is used. However, not only this, but, for example, a rare gas other than argon may be used.

After the substrate 30 is disposed in the first space SP1, the inert gas G is introduced into the first space SP1, in which the target T and the substrate 30 are disposed, to execute sputtering to laminate Ni contained in the target T on the surface 30a of the substrate 30 (Step S12; a laminating step). Specifically, in this step, the inert gas G is introduced from the inert gas supply unit M1 into the first space SP1 in a state in which the first space SP1 is evacuated. Then, by applying a negative voltage to the target T, the inert gas G is ionized and the ionized inert gas G is caused to collide with the surface of the substrate 30. Accordingly, components (atoms and molecules) contained in the target T, here, Ni contained in the target T, are repelled from the target T and laminated on the surface 30a of the substrate 30. A laminated body containing Ni laminated on the surface 30a of the substrate 30 is hereinafter described as laminated body 34A.

Note that the component ejected from the target T and laminated as the laminated body 34A is not limited to Ni, and other components (for example, NiOₓ) such as atoms and molecules included in the target T may also be ejected from the target T and laminated as the laminated body 34A. That is, the laminated body 34A can be considered a layer containing at least Ni.

In the laminating step, as explained above, the inert gas G is introduced into the first space SP1 in the state in which the first space SP1 is evacuated. The evacuating here may indicate, for example, setting pressure to 10 Pa or less. The same applies below. In the laminating step, the inert gas G is preferably introduced such that the pressure in the first space SP1 is preferably less than 0.5 Pa, more preferably 0.4 Pa or less, and more preferably 0.3 Pa or less. That is, in this step, it is preferable to set the air pressure in the first space SP1 containing the inert gas G to be in the range explained above. By setting the first space SP to such an air pressure, it is possible to reduce an energy loss of sputter particles, form the NiOₓ layer 34 having high hardness and smoothness, and improve scratch resistance.

Subsequently, the substrate 30 on which the laminated body 34A is laminated is disposed in a second space SP2 (Step S14). An oxygen supply unit M2 is connected to the second space SP2. The oxygen supply unit M2 is a device that supplies oxygen O.

After the substrate 30 is disposed in the second space SP2, oxygen plasma (plasma-like oxygen) is generated in the second space SP2 to oxidize the laminated body 34A laminated on the substrate 30 to form the NiOₓ layer 34 on the substrate 30 (Step S16; an oxidation step).

Specifically, in a state in which the second space SP2 is evacuated, the oxygen O is supplied from the oxygen supply unit M2 into the second space SP2. The oxygen O in the second space SP2 is turned into plasma to generate oxygen plasma. In the second space SP2, the generated oxygen plasma comes into contact with the laminated body 34A laminated on the substrate 30 to oxidize the laminated body 34A and form the NiOₓ layer 34 on the substrate 30. That is, Ni contained in the laminated body 34A is oxidized by oxygen plasma to be NiOₓ. It is considered that hardness is increased because volume expansion of a film occurs in an oxidation process and the film is densified. Accordingly, the laminated body 34A changes to the NiOₓ layer 34 containing NiOₓ as a main component. The NiOₓ layer 34 is formed on the substrate 30. Not only the oxygen plasma but also oxygen radicals and oxygen ions may be generated and oxidized.

The target T contains Ni. In the target T, a content of Ni with respect to the entire target T is preferably 50 atomic or more and 100 atomic % or less, more preferably 60 atomic or more and 100 atomic % or less, 70 atomic % or more and 100 atomic % or less, and 80 atomics or more and 100 atomic % or less. Since the content of Ni in the target T is in this range, it is possible to increase the volume expansion coefficient of the film in the oxidation process, form the NiOₓ layer 34 having high hardness because the film density is increased, and improve scratch resistance. Note that the target T may contain NiOₓ as a component other than Ni.

In the oxidation step, it is preferable supply the oxygen O of 10 sccm or more and 60 sccm or less as a total flow rate of 80 sccm into the second space SP2, turn the supplied oxygen O into plasma to form oxygen plasma. Furthermore, in the oxidation step, the oxygen O of more preferably 20 sccm or more and 60 sccm or less and still more preferably 20 sccm or more and 40 sccm or less may be supplied to the second space SP2. Since a required amount of oxygen varies depending on the size of a chamber (equivalent to the size of the second space SP2), an oxygen flow rate ratio in the total amount of gas in the second space SP2 is preferably 10% or more and 75% or less, more preferably an oxygen ratio of 12% or more and 75% or less, and still more preferably an oxygen ratio of 25% or more and 50% or less. In other words, in the oxidation step, it can be said that it is preferable to turn the oxygen O having a flow rate in the range described above into plasma to form oxygen plasma. By setting the supply amount of oxygen O in the range described above, it is possible to appropriately oxidize Ni and form the NiOₓ layer 34 having high hardness without reducing the transmittance and the average transmittance of a far infrared ray. It is possible to improve scratch resistance.

In the oxidation step, oxygen plasma may be generated by any method. However, for example, an electrode may be provided in the second space SP2 and the oxygen O in the second space SP2 may be turned into plasma by applying a voltage to the electrode to generate oxygen plasma. In this case, electric power applied to the electrode is preferably 2 kW or more and 4 kW or less and more preferably 3 kW or more and 4 kW or less. By setting the applied power in the range described above, it is possible to appropriately oxidize Ni and form the NiOₓ layer 34 having high hardness. It is possible to improve scratch resistance.

In the present embodiment, the process from Step S10 to Step S16 may be repeated to form the NiOₓ layer 34 to be gradually thicker.

Note that, in the present embodiment, the first space SP1 and the second space SP2 are separate spaces (chambers) and the NiOₓ layer 34 is formed by performing the laminating step and the oxidation step while moving the substrate 30 from the first space SP1 to the second space SP2 or from the second space SP2 to the first space SP1. A method of moving the substrate 30 between the first space SP1 and the second space SP2 may be optional. For example, the substrate 30 may be attached to the surface of a rotatable drum and the first space SP1 and the second space SP2 may be formed to be aligned in a rotating direction of the drum. In this case, the rotation of the drum moves the substrate 30 from the first space SP1 to the second space SP2 (or from the second space SP2 to the first space SP1).

The first space SP1 and the second space SP2 may be the same space (chamber). In this case, in a state in which the substrate 30 is disposed in the space, after evacuating the space, while the inert gas G being introduced, a voltage may be applied to the target T to perform sputtering, and, thereafter, oxygen plasma may be supplied into the space to oxidize the laminated body 34A to form the NiOₓ layer 34.

### (Effects)

As explained above, the far-infrared transmitting member 20 according to the present embodiment includes the substrate 30 that transmits a far infrared ray and the functional film (the first functional film 32) formed on the substrate 30 and including the NiOₓ layer 34 containing NiOₓ as a main component. In the far-infrared transmitting member 20, the average transmittance of light having a wavelength of 8 μm to 12 μm is 50% or more and the hardness measured by the nanoindentation method is 10 GPa or more.

Here, the far-infrared transmitting member is required to appropriately transmit a far infrared ray and improve scratch resistance. Since the far-infrared transmitting member 20 according to the present embodiment is provided with the NiOₓ layer 34 containing NiOₓ as a main component, the far-infrared transmitting member 20 can appropriately transmit a far infrared ray and improve scratch resistance. Furthermore, for example, although diamond-like carbon (DLC) or the like can also improve scratch resistance, the DLC has a limited film forming process and requires elastic modulus control or the like. Therefore, a load in a film forming process increases. In contrast, by using the NiOₓ layer 34 containing NiOₓ as a main component as in the present embodiment, it is possible to improve scratch resistance while reducing the load in the film forming step.

In addition, in the manufacturing method according to the present embodiment, the far-infrared transmitting member 20 is manufactured by forming, with the post-oxidation sputtering method, on the substrate 30 that transmits a far infrared ray, the NiOₓ layer 34 containing NiOₓ as a main component. By using the post-oxidation sputtering method, it is possible to form the NiOₓ, layer 34 having high hardness of 10 GPa or more measured by the nanoindentation method. Therefore, it is possible to appropriately transmit a far infrared ray and improve scratch resistance.

The manufacturing method according to the present embodiment preferably includes the laminating step and the oxidation step. In the laminating step, the inert gas G is introduced into the first space SP1, in which the target T containing Ni and the substrate 30 are disposed, to laminate, on the substrate 30, the laminated body 34A containing Ni in the target T. In the oxidation step, the substrate 30, on which the laminated body 34A is laminated, is disposed in the second space SP2 and oxygen plasma is generated in the second space SP2 to oxidize the laminated body 34A laminated on the substrate 30 and form the NiOₓ layer 34 on the substrate 30. By using the post-oxidation sputtering method as explained above, it is possible to form the NiOₓ layer 34 having high hardness of 10 GPa or more measured by the nanoindentation method. Therefore, it is possible to appropriately transmit a far infrared ray and improve scratch resistance.

### (Another Example)

Next, another example of a laminate structure of the far-infrared transmitting member 20 is explained.

### (Outermost Layer)

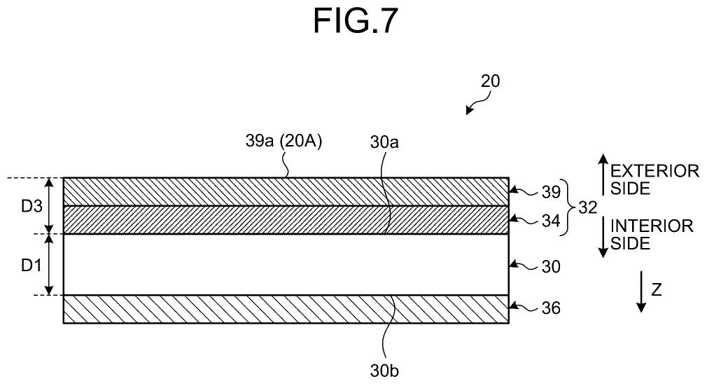

FIG. 7 is a schematic cross-sectional view of a far-infrared transmitting member according to another example of the present embodiment. As illustrated in FIG. 7, the first functional film 32 may include the outermost layer 39. The outermost layer 39 is a layer provided further on the side of the first functional film 32 opposite to the substrate 30 than the NiOₓ layer 34 (further on the exterior side than the NiOₓ layer 34 in the present embodiment). That is, the outermost layer 39 is a layer provided on the outermost side (the most exterior side in the present embodiment) in the first functional film 32. In other words, the outermost layer 39 is the outermost side layer of the far-infrared transmitting member 20 and is exposed to the outside. Therefore, the surface 39a of the outermost layer 39 on the exterior side is the surface 20A of the far-infrared transmitting member 20.

Note that, in the example illustrated in FIG. 7, the first functional film 32 includes only the NiOₓ layer 34 and the outermost layer 39. However, not only this, but the first functional film 32 may further include at least one of a hue adjustment layer and an adhesion layer explained below. That is, the first functional film 32 may include at least one of the outermost layer 39, the hue adjustment layer, and the adhesion layer in addition to the NiOₓ layer 34.

The outermost layer 39 is preferably a film equivalent to or harder than the NiOₓ layer 34. Even when the outermost layer 39 is provided, the maximum value Hₘₐₓ of the indentation hardness H of the far-infrared transmitting member 20 may be in the numerical value range explained above. By forming such a hard outermost layer 39 on the surface, it is possible to appropriately protect the far-infrared transmitting member 20 from wiping with a wiper, scratching by dust, and the like.

In the outermost layer 39, a refractive index with respect to light (visible light) having a wavelength of 550 nm is preferably 2.5 or less, more preferably 1.5 or more and 2.5 or less, and still more preferably 1.7 or more and 2.4 or less. In the outermost layer 39, an average refractive index with respect to light having a wavelength of 380 nm to 780 nm is preferably 2.5 or less, more preferably 1.5 or more and 2.5 or less, and still more preferably 1.7 or more and 2.4 or less. Since the refractive index and the average refractive index of the outermost layer 39 with respect to visible light are in this numerical value range, it is possible to suppress reflection of visible light and make the far-infrared transmitting member 20 less conspicuous.

In the outermost layer 39, a refractive index with respect to light having a wavelength of 10 μm (a far infrared ray) is preferably 0.5 or more and 3.5 or less, more preferably 0.7 or more and 2.5 or less, and still more preferably 1.0 or more and 2.5 or less. In the outermost layer 39, an average refractive index with respect to light having a wavelength of 8 μm to 12 μm is preferably 0.5 or more and 3.5 or less, more preferably 0.7 or more and 2.5 or less, and still more preferably 1.0 or more and 2.5 or less. Since the refractive index and the average refractive index of the outermost layer 39 with respect to a far infrared ray are in this numerical value range, it is possible to suppress reflection of the far infrared ray and appropriately transmit the far infrared ray.

The outermost layer 39 is capable of transmitting a far infrared ray. In the outermost layer 39, an extinction coefficient with respect to light having a wavelength of 10 μm is preferably 0.4 or less, preferably 0.2 or less, and more preferably 0.1 or less. In the outermost layer 39, an average extinction coefficient with respect to light having a wavelength of 8 μm to 12 μm is preferably 0.4 or less, preferably 0.2 or less, and more preferably 0.1 or less. Since the extinction coefficient and the average extinction coefficient are in this range, it is possible to appropriately transmit a far infrared ray.

The thickness of the outermost layer 39 is preferably 0.01 μm or more and 1 μm or less, more preferably 0.02 μm or more and 0.5 μm or less, and still more preferably 0.05 μm or more and 0.3 μm or less. Since the thickness is in this range, it is possible to appropriately suppress reflection of a far infrared ray and visible light. Note that the thickness of the outermost layer 39 can also be considered the length in the Z direction from the surface on the Z-direction side to the surface on the opposite side to the Z direction of the outermost layer 39.

The material of the outermost layer 39 is optional. For example, the material is preferably a material containing at least one kinds of material selected from a group of ZrO₂, Al₂O₃, TiO₂, Si₃N₄, AlN, MgF₂, YF₃, and diamond-like carbon. Since such a material is used, the outermost layer 39 can ensure chemical stability of the far-infrared transmitting member 20 and appropriately protect the far-infrared transmitting member 20.

The outermost layer 39 preferably has a water barrier property in order to protect the far-infrared transmitting member 20 from water. The water barrier performance of the outermost layer 39 varies depending on a material, a crystal structure, and a film thickness. The outermost layer 39 preferably has an amorphous structure from the viewpoint of the water barrier property The outermost layer 39 preferably has a low friction coefficient. Further, the outermost layer 39 may have a wettability improving function.

Note that the outermost layer 39 may also be formed by the post-oxidation sputtering method like the NiOₓ layer 34. However, not only this, but a formation method may be optional. The outermost layer 39 may be formed by, for example, sputtering (for example, reactive sputtering) other than the post-oxidation sputtering method or vapor deposition.

### (Hue Adjustment Layer)

In the first functional film 32, a hue adjustment layer may be provided between the NiOₓ layer 34 and the outermost layer 39 side (further on the exterior side than the NiOₓ layer 34 in the present embodiment). The hue adjustment layer is a layer for securing designability by reducing a difference in reflectance (reflectance dispersion) with respect to visible lights having different wavelengths and suppressing an interference color of the far-infrared transmitting member 20.

The hue adjustment layer is capable of transmitting a far infrared ray. The hue adjustment layer may be configured by only one layer or may be configured by laminating a plurality of layers.

The hue adjustment layer may be formed by a post-oxidation sputtering method like the NiOₓ layer 34. However, not only this, but a formation method may be optional. The hue adjustment layer may be formed by, for example, sputtering (for example, reactive sputtering) other than the post-oxidation sputtering method or vapor deposition.

In the hue adjustment layer, a refractive index with respect to light (visible light) having a wavelength of 550 nm may be different from the refractive index of the NiOₓ layer 34 with respect to light (visible light) having a wavelength of 550 nm. In the hue adjustment layer, a refractive index with respect to light (visible light) having a wavelength of 550 nm is preferably 2.2 or more and 2.5 or less and more preferably 2.3 or more and 2.4 or less. Since the refractive index of the hue adjustment layer with respect to the visible light is in this numerical value range, it is possible to suppress reflection and dispersion of the visible light and make the far-infrared transmitting member 20 less conspicuous.

The hue adjustment layer is capable of transmitting a far infrared ray. In the hue adjustment layer, an extinction coefficient with respect to light having a wavelength of 10 μm is 0.4 or less, preferably 0.2 or less, and more preferably 0.1 or less. Since the extinction coefficient is in this range, it is possible to appropriately transmit a far infrared ray.

The thickness of the hue adjustment layer is preferably 5 nm or more and 100 nm or less, more preferably 10 nm or more and 60 nm or less, and still more preferably 20 nm or more and 50 nm or less. A ratio of the thickness of the hue adjustment layer to the thickness D2 of the NiOₓ layer 34 is preferably 0.5% or more and 10% or less, more preferably 1% or more and 6% or less, and still more preferably 2% or more and 5% or less. Since the thickness of the hue adjustment layer is in this range, it is possible to suppress reflection and dispersion of visible light while appropriately transmitting a far infrared ray and make the far-infrared transmitting member 20 less conspicuous. Note that the thickness of the hue adjustment layer can also be considered length in the Z direction from the surface on the Z direction side to the surface on the opposite side to the Z direction of the hue adjustment layer.

In this example, the hue adjustment layer includes a first layer and a second layer provided on the NiOₓ layer 34 side (the exterior side) of the first layer.

In this example, the first layer is a layer containing ZrO₂ as a main component. In the first layer, a content of ZrO₂ is 50 mass % or more and 100 mass % or less, preferably 70 mass % or more and 100 mass % or less, and more preferably 90 mass % or more and 100 mass % or less with respect to the entire first layer. In the first layer, the content of a simple substance of ZrO₂, that is, ZrO₂ excluding an inevitable impurity is preferably 100 mass %. The first layer may contain an accessory component, which is a component other than ZrO₂ serving as the main component. The accessory component is preferably an oxide that transmits a far infrared ray. Examples of the accessory component include NiOₓ, ZnO, Bi₂O₃, and CuOₓ.

The first layer is capable of transmitting a far infrared ray. In the first layer, an extinction coefficient with respect to light having a wavelength of 10 μm is preferably 0.10 or less, more preferably 0.05 or less, and still more preferably 0.04 or less.

In the first layer, a refractive index with respect to light (visible light) having a wavelength of 550 nm is preferably 2.05 or more, more preferably 2.05 or more and 2.40 or less, still more preferably 2.10 or more and 2.30 or less, and particularly preferably 2.15 or more and 2.25 or less.

The thickness of the first layer is preferably 10 nm or more and 40 nm or less, more preferably 15 nm or more and 35 nm or less, and still more preferably 20 nm or more and 30 nm or less. A ratio of the thickness of the first layer to the thickness D2 of the NiOₓ layer 34 is preferably 1, or more and 41 or less, more preferably 1.5% or more and 3.5% or less, and still more preferably 2% or more and 3, or less.

In this example, the second layer is a layer having the same material and the same characteristics as those of the NiOₓ layer 34. However, the thickness of the second layer is preferably 5 nm or more and 40 nm or less, more preferably 5 nm or more and 25 nm or less, and still more preferably 10 nm or more and 30 nm or less. A ratio of the thickness of the second layer to the thickness D2 of the NiOₓ layer 34 is preferably 0.5, or more and 4% or less, more preferably 0.5% or more and 2.5% or less, and still more preferably 1% or more and 3% or less.

In this example, the hue adjustment layer includes two layers of the first layer and the second layer. However, not only this, but a plurality of layers of a laminated body of the first layer and the second layer may be laminated. The hue adjustment layer is preferably a layer obtained by laminating 2n (n is a natural number equal to or larger than 1) layers of the first layer and the second layer from the substrate 30 side. A film thickness ratio of the layers in the hue adjustment layer is preferably higher in a layer having a lower refractive index with respect to light (visible light) having a wavelength of 550 nm. Since the laminating order and the number of layers of the hue adjustment layer is in this range, it is possible to suppress reflection and dispersion of visible light and make the far-infrared transmitting member 20 less conspicuous.

However, the configuration of the hue adjustment layer is not limited to the configuration including the first layer containing ZrO₂ as a main component and the second layer made of the same material as the NiOₓ layer 34 and may be any configuration.

### (Adhesion Layer)

An adhesion layer may be formed between the NiOₓ layer 34 and the substrate 30. The adhesion layer is a film that sticks the substrate 30 and the NiOₓ layer 34, in other words, a film that improves an adhesive force between the substrate 30 and the NiOₓ layer 34.

In the adhesion layer, a refractive index with respect to light having a wavelength of 10 μm is preferably 1.0 or more and 4.3 or less, more preferably 1.5 or more and 4.3 or less, and still more preferably 1.5 or more and 3.8 or less. Since the refractive index is in this range, it is possible to appropriately suppress reflection of a far infrared ray.

The thickness of the adhesion layer is preferably 0.05 μm or more and 0.5 μm or less, more preferably 0.05 μm or more and 0.3 μm or less, and still more preferably 0.05 μm or more and 0.1 μm or less. Since the thickness of the adhesion layer is in this range, it is possible to appropriately stick the substrate 30 and the NiOₓ layer 34 while appropriately suppressing reflection of a far infrared ray. Note that the thickness of the adhesion layer can also be considered length in the Z direction from the surface on the Z direction side to the surface on the opposite side to the Z direction of the adhesion layer. The thickness of the adhesion film 40 is preferably smaller than the thickness D2 of the NiOₓ layer 34. Since the thickness of the adhesion film 40 is smaller than the thicknesses of these layers, it is possible to reduce the influence on optical performance.

The adhesion layer is capable of transmitting a far infrared ray. In the adhesion layer, an extinction coefficient with respect to light having a wavelength of 10 μm is 0.4 or less, preferably 0.2 or less, and more preferably 0.1 or less. Since the extinction coefficient is in this range, it is possible to appropriately transmit a far infrared ray.

The material of the adhesion layer is optional. The material is preferably a material containing at least one material selected out of a group of Si, Ge, MgO, NiOₓ, CuOₓ, ZnS, Al₂O₃, ZrO₂, SiO₂, TiO₂, ZnO, and Bi₂O₃ and more preferably a material containing ZrO₂. Since such a material is used for the adhesion layer, it is possible to appropriate stick the substrate 30 and the hue adjustment layer.

Note that, like the NiOₓ layer 34, the adhesion layer may also be formed by the post-oxidation sputtering method. However, not only this, but a formation method may be optional. the adhesion layer may be formed by, for example, sputtering (for example, reactive sputtering) other than the post-oxidation sputtering method or vapor deposition.

### EXAMPLES

In the following explanation, the present invention is specifically explained with reference to examples. However, the present invention is not limited to the examples. Tables 1 and 2 are tables illustrating far-infrared transmitting members in the examples.

TABLE 1

| | | Example 1 | Example 2 | Example 3 | Example 4 | Example 5 | Example 6 | Example 7 | Example 8 | Example 9 |
|---|---|---|---|---|---|---|---|---|---|---|
| Film 1 | Film type | NiOₓ | NiOₓ | NiOₓ | NiOₓ | NiOₓ | NiOₓ | NiOₓ | NiOₓ | NiOₓ |
| | Film | 1200 | 1250 | 1250 | 1250 | 1250 | 1250 | 1250 | 1250 | 1250 |
| | thickness | | | | | | | | | |
| | (nm) | | | | | | | | | |
| Substrate | Material | Si | Si | Si | Si | Si | Si | Si | Si | Si |
| | Thickness | 0.525 | 2 | 2 | 2 | 2 | 2 | 2 | 2 | 2 |
| | (mm) | | | | | | | | | |
| Process | Sputter | RF | Reactive | Post-oxidation sputter | | | | | | |
| conditions | method | magnetron | sputter | | | | | | | |
| | | sputter | | | | | | | | |
| | Ni element | 100 | 61 | 61 | 69 | 69 | 69 | 69 | 69 | 69 |
| | ratio (at %) | | | | | | | | | |
| | in target | | | | | | | | | |
| | Oxygen flow | 10 | 20 | 13 | 13 | 31 | 50 | 75 | 13 | 75 |
| | rate ratio (%) | | | | | | | | | |
| | RF power | — | — | 2 | 2 | 2 | 2 | 2 | 3 | 3 |
| | (kW) | | | | | | | | | |
| | Film formation | 0.35 | 0.24 | 0.20 | 0.20 | 0.20 | 0.20 | 0.20 | 0.20 | 0.20 |
| | pressure (Pa) | | | | | | | | | |
| Physical | Ra (nm) | — | 7.9 | 2.5 | 5.7 | 2.1 | 2.1 | 2.7 | 5.7 | 2.1 |
| property | Hₘₐₓ (GPa) | 6.1 | 6.8 | 11.3 | 10.3 | 13.9 | 15.1 | 17.3 | 11.2 | 20.6 |
| values | E (GPa) | 155.7 | 165.0 | 249.7 | 218.3 | 227.6 | 239.0 | 240.0 | 223.7 | 245.0 |
| | Hₘₐₓ/E | 0.039 | 0.041 | 0.045 | 0.047 | 0.061 | 0.063 | 0.072 | 0.050 | 0.084 |
| | FIR-T (%) | — | 69.4 | 69.4 | 74.3 | 73.0 | 71.6 | 67.9 | 74.2 | 58.9 |
| Evaluation | Number of | — | 13 | 1 | 0 | 0 | 0 | 0 | 1 | 0 |
| result | scratches in | | | | | | | | | |
| | wiper test | | | | | | | | | |
| | Scratch | — | X | ◯ | ◯ | ◯ | ◯ | ◯ | ◯ | ◯ |
| | resistance | | | | | | | | | |
| | evaluation | | | | | | | | | |
| | result | | | | | | | | | |

TABLE 2

| | | Exam- | Exam- |
|---|---|---|---|
| | | ple 10 | ple 11 |
| Film 4 | Film type | ZrO₂ | |
| | Film thickness (nm) | 200 | |
| Film 3 | Film type | NiOₓ | |
| | Film thickness (nm) | 15 | |
| Film 2 | Film type | ZrO₂ | ZrO₂ |
| | Film thickness (nm) | 25 | 200 |
| Film 1 | Film type | NiOₓ | NiOₓ |
| | Film thickness (nm) | 1050 | 1150 |
| Substrate | Material | Si | Si |
| | Thickness (mm) | 2 | 2 |
| Process | Sputter method | Post-oxidation | |
| conditions | | sputter | |
| | Oxygen flow rate ratio (%) | 13 | 13 |
| | Ni element ratio (at %) in target | 61 | 61 |
| | RF power (kW) | 2 | 2 |
| | Film formation pressure (Pa) | 0.21 | 0.21 |
| Physical | Ra (nm) | 2.6 | 3.0 |
| property values | Hₘₐₓ (GPa) | 13.5 | 12.5 |
| | FIR-T (%) | 68.9 | 68.4 |
| Evaluation result | Number of scratches in wiper test | 0 | 0 |
| | Δa*b* | 1.7 | 10.7 |

### Example 1

A far-infrared transmitting member was manufactured by applying the data in Table 3 of Non-Patent Literature 1. NiOₓ layers were respectively formed on both surfaces of a substrate made of Si (100 orientation, P type), both the surfaces of which were mirror-polished, by an RF magnetron sputtering method to obtain a far-infrared transmitting member. The thickness of the substrate was set to 0.525 mm and the thickness of the NiOₓ layer was set to 1200 nm. Note that the thickness of a substrate was measured with a digital caliper (CD-15CX manufactured by Mitutoyo Corporation). The thickness of a functional film was evaluated by a stylus profiling system (Dektak XT-S, manufactured by BRUKER Corporation).

### Example 2

As illustrated in Table 1, in an example 2, a NiOₓ film (a first film) was formed on a substrate made of Si (FZ grade) by a reactive sputtering method using a carousel type sputtering device. The thicknesses of the substrate and the NiOₓ film were as illustrated in Table 1.

Film formation conditions of the NiOₓ film are as follows and a part thereof is illustrated in Table 1 as well. A film formation pressure was adjusted according to an APC valve opening degree of a turbo molecular pump.

### (Film Formation Conditions of the Example 2)

Ni content of target: elemental ratio 61%
Target: Ni (30 mass %)+NiO (70 mass %) mixed target
Sputtering gas: Ar
Ar flow rate: 120 sccm
Reactive gas: O₂
Oxygen flow rate: 30 sccm
Supplied power (output): 3000 W
Substrate temperature: room temperature

### Example 3

As illustrated in Table 1, in an example 3, a NiOₓ film (a first film) was formed on the same substrate as the substrate in the example 2 by a post-oxidation sputtering method using a load lock type sputtering device (RAS-1100BII, manufactured by SYN Corporation). The thicknesses of the substrate and the NiOₓ film were as illustrated in Table 1.

Film formation conditions of the NiOₓ film are as follows and a part thereof is illustrated in Table 1 as well. Note that RF power is electric power applied to an electrode when oxygen is turned into plasma.

### (Film Formation Conditions of the Example 3)

Ni content of target: elemental ratio 61%
Target: Ni (30 mass %)+NiO (70 mass %) mixed target

### [Laminating Step]

Sputtering power: 6 kW
Sputtering gas: Ar
Ar flow rate: 150 sccm

### [Oxidation Step]

Reactive gas: Ar+O₂
Oxygen flow rate: 10 sccm
Argon flow rate: 70 sccm
Substrate temperature: room temperature

### Examples 4 to 9

In Examples 4 to 9, a NiOₓ film (a first film) was formed by the same method as the method in the example 3 under conditions except the conditions illustrated in Table 1.

### Example 4

### [Oxidation Step]

Reactive gas: Ar+O₂
Oxygen flow rate: 10 sccm
Argon flow rate: 70 sccm
Substrate temperature: room temperature

### Example 5

### [Oxidation Step]

Reactive gas: Ar+O₂
Oxygen flow rate: 25 sccm
Argon flow rate: 55 sccm
Substrate temperature: room temperature

### Example 6

### [Oxidation Step]

Reactive gas: Ar+O₂
Oxygen flow rate: 40 sccm
Argon flow rate: 40 sccm
Substrate temperature: room temperature

### Example 7

### [Oxidation Step]

Reactive gas: Ar+O₂
Oxygen flow rate: 60 sccm
Argon flow rate: 20 sccm
Substrate temperature: room temperature

### Example 8

### [Oxidation Step]

Reactive gas: Ar+O₂
Oxygen flow rate: 10 sccm
Argon flow rate: 70 sccm
Substrate temperature: room temperature

### Example 9

### [Oxidation Step]

Reactive gas: Ar+O₂
Oxygen flow rate: 60 sccm
Argon flow rate: 20 sccm
Substrate temperature: room temperature

### Examples 10 to 11

In Examples 10 to 11, a laminated film of a NiOₓ film (a first film) and a ZrO₂ film was formed on the same substrate as the substrate in the example 3 by the same method as the method in the example 3 under conditions except the conditions illustrated in Table 2. The thicknesses of the substrate and the layers were set to the thicknesses illustrated in Table 2. Note that the physical property values described in Table 2 indicate physical property values of a layer to be the outermost layer when viewed from the substrate. Note that the process conditions described in Table 2 indicate film formation conditions for the NiOₓ film.

### Examples 10 to 11

### (NiOₓ Film Formation Conditions)

### [Laminating Step]

Sputtering power: 6 kW
Sputtering gas: Ar
Ar flow rate: 120 sccm

### [Oxidation Step]

Reactive gas: Ar+O₂
Oxygen flow rate: 10 sccm
Argon flow rate: 70 sccm
Substrate temperature: room temperature
(ZrO₂ film formation conditions)

### [Laminating Step]

Target: Zr target
Sputtering power: 6 kW
Sputtering gas: Ar
Sputtering gas flow rate: 150 sccm

### [Oxidation Step]

Reactive gas: O₂
Oxygen flow rate: 100 sccm
RF power: 4 kW
Substrate temperature: room temperature
Film formation pressure: 0.21 Pa

### (Average Transmittance of Light Having Wavelength of 8 μm to 12 μm)

Physical property values of the far-infrared transmitting members of the example were measured.

An infrared transmittance (FIR-T) of an NiOₓ film formed on a Ge substrate was measured as a physical property value. As a measurement method, the transmittance of light having a wavelength of each of 2500 nm to 25000 nm was measured using a Fourier transform infrared spectrometer (manufactured by ThermoScientific Inc., product name: Nicolet iS10) and a refractive index and an extinction coefficient of the film were analyzed from the measured transmittance. Based on analyzed values, an average transmittance at a wavelength of 8 μm to 12 μm in a film configuration when used as the far-infrared transmitting member was calculated using an optical simulation. The optical simulation was performed using simulation software (manufactured by HULINX Corporation, TFCalc).

(Arithmetic Average Roughness Ra) As physical property values, the arithmetic average roughness Ra of the surface of the first film (the NiOₓ film) of the far-infrared transmitting member was measured based on JIS B0601.

### (Maximum Value Hₘₐₓ of the Indentation Hardness H)

As a physical property value, the indentation hardness H of the surface of the first film (the NiOₓ film) of the far-infrared transmitting member was measured. As the indentation hardness H, the indentation hardness H in the thickness direction (the depth direction) of the first functional film was measured by a nanoindentation method using an iMicro nanoindenter (manufactured by KLA Corporation). Measurement conditions are as follows.
Indenter: Berkovich
Actuator: IF50
Measurement method: Continuous stiffness measurement method
Maximum indentation load: 50 mN
Strain rate: 0.2%/s
Poisson's ratio of sample:0.25
Number of measurement points: fifteen to twenty points per one substrate
As the maximum value Hₘₐₓ of the indentation hardness H, a maximum value of the indentation hardness H at an indentation depth of 40 to 110 nm was adopted.

Measurement results of the physical property values of the examples are illustrated in Tables 1 and 2.

As illustrated in Table 1, in the example 1 in which the NiOₓ layer was manufactured by the RF magnetron sputter and the example 2 in which the NiOₓ layer was formed by the reactive sputtering method, the maximum value Hₘₐₓ of the indentation hardness H was 10 GPa or less, and the NiOₓ layer having low mechanical strength was obtained. On the other hand, in the examples 3 to 11 in which the NiOₓ layer was formed by the post-oxidation sputtering method, the NiOₓ layer having high mechanical strength in which the maximum value Hₘₐₓ of the indentation hardness H was 10 GPa or more was obtained. Above all, in the examples 5 to 7 and 9 in which the NiOₓ layer was formed by the post-oxidation sputtering method and the O₂ gas flow rate ratio in the reaction process region at the time of film formation was 25% or more, the NiOₓ layer having very high mechanical strength in which the maximum value Hₘₐₓ of the indentation hardness H was 12 GPa or more was obtained.

### (Evaluation)

The far-infrared transmitting members of the examples were evaluated. As the evaluation, a wiper test was carried out and the number of scratches formed by the wiper test was measured. Specifically, the wiper test was performed on the surface of the first film (the NiOₓ film) under the following conditions. Thereafter, a dark field observation was performed at magnification of 350 using an optical microscope DSX500 (manufactured by OLYMPUS Corporation) for a sliding position where a wiper was slid. In the dark field observation, the number of scratches in a region of 1.8 mm was measured perpendicularly to a sliding direction.

The wiper test was performed by abrading a surface on the most distant side (the outermost side) from the substrate using a traverse type abrasion tester under the following test conditions. A wiper rubber (genuine product for Toyota cars, model number 85214-47170) was attached to the traverse type abrasion tester, a dust solution was dropped between the wiper and a sample, and reciprocating friction was performed while applying a contact load to the wiper. A wiper width was 20 mm, a stroke width was 40 mm, the number of strokes was 2500 reciprocations, and a load was equivalent to 50 g. The dust solution was prepared by mixing eight types of JIS test powder 1 and pure water at a mass ratio of 3:100 and 2 ml of the dust solution was dropped to a sliding part. The substrate was cleaned every 500 reciprocations and the dust solution was dropped again to perform reciprocating friction of 2500 reciprocations in total.

When the number of scratches in the wiper test was five or less, the wiper test was regarded as successful and, when the number of scratches was more than five, the wiper test was regarded as unsuccessful. As illustrated in Table 1, in the example 2, which is a comparative example, the wiper test is unsuccessful because the maximum value Hₘₐₓ of the indentation hardness H is low. It is presumed that scratch resistance cannot be improved while a far infrared ray being appropriately transmitted. On the other hand, in the examples 3 to 11, which are examples, the wiper test is successful. It is seen that scratch resistance can be improved while a far infrared ray being appropriately transmitted.

### (Optional Evaluation)

As an optional evaluation, Δa*b* was evaluated for the far-infrared transmitting members in the examples 10 and 11. A reflection spectrum in a visible region was measured using U4100 (manufactured by Hitachi, Ltd.) based on JIS R3106, a chromaticity coordinate L*a*b* of reflected light in a CIE-Lab color coordinate system at the time when the standard illuminant D65 was used for illumination light was calculated based on JIS Z 8781-4, and Δa*b* was calculated based on the Expression (3) described above. When Δa*b* is 5 or less, visible light reflected from the far-infrared transmitting member 20 changes to a neutral color. An appearance that secures designability can be obtained. As illustrated in Table 2, in Example 11, Δa*b* was reduced by adding the hue adjustment layer and designability was improved.

Although the embodiment of the present invention is explained above, the embodiment is not limited by the contents of the embodiment. The constituent elements explained above include those that can be easily assumed by those skilled in the art, those that are substantially the same, and those in a so-called scope of equivalents. Further, the constituent elements explained above can be combined as appropriate. Furthermore, various omissions, substitutions, or changes of the constituent elements can be made without departing from the gist of the embodiment explained above.

### REFERENCE SIGNS LIST

1 VEHICLE GLASS
10, 12, 14 GLASS SUBSTRATE
20 FAR-INFRARED TRANSMITTING MEMBER
30 SUBSTRATE
32 FIRST FUNCTIONAL FILM (FUNCTIONAL FILM)
34 NiOₓ LAYER
36 SECOND FUNCTIONAL FILM

1. A far-infrared transmitting member comprising:
a substrate that transmits a far infrared ray; and
a functional film formed on the substrate and including one or more NiOₓ layers containing NiOₓ as a main component, wherein
an average transmittance of light having a wavelength of 8 μm to 12 μm is 50, or more, and
a maximum value Hₘₐₓ of indentation hardness in a range of an indentation depth of 40 nm or more and 110 nm or less from a surface of the functional film measured by a nanoindentation method is 10 GPa or more.

2. The far-infrared transmitting member according to claim 1, wherein a ratio Hₘₐₓ/E of the maximum value Hₘₐₓ of the indentation hardness and a Young's modulus E is 0.045 or more and 0.120 or less.

3. The far-infrared transmitting member according to claim 1, wherein an arithmetic average roughness Ra is 6 nm or less.

4. The far-infrared transmitting member according to claim 1, wherein, in the NiOₓ, layer, an extinction coefficient with respect to light having a wavelength of 10 μm is 0.4 or less.

5. The far-infrared transmitting member according to claim 1, wherein the NiOₓ layer is formed on an outermost side.

6. The far-infrared transmitting member according to claim 1, wherein the far-infrared transmitting member is mounted on a vehicle.

7. The far-infrared transmitting member according to claim 6, wherein the far-infrared transmitting member is disposed in a window member of the vehicle.

8. The far-infrared transmitting member according to claim 6, wherein the far-infrared transmitting member is disposed in an exterior member for a pillar of the vehicle.

9. The far-infrared transmitting member according to claim 6, wherein the far-infrared transmitting member is disposed in a light blocking region of an exterior member for the vehicle.

10. A method of manufacturing a far-infrared transmitting member, the method comprising forming a NiOₓ layer containing NiOₓ as a main component on a substrate that transmits a far infrared ray with a post-oxidation sputtering method to manufacture the far-infrared transmitting member.

11. The method of manufacturing the far-infrared transmitting member according to claim 10, further comprising:
a laminating step of introducing an inert gas into a first space, in which a target containing Ni and the substrate are disposed, to laminate, on the substrate, a laminated body containing Ni in the target; and
an oxidation step of disposing the substrate, on which the laminated body is laminated, in a second space and generating oxygen plasma in the second space to oxidize the laminated body laminated on the substrate to form the NiOₓ layer on the substrate.

12. The method of manufacturing the far-infrared transmitting member according to claim 11, wherein, in the laminating step, pressure in the first space is set to less than 0.5 Pa.

13. The method of manufacturing the far-infrared transmitting member according to claim 11, wherein, in the laminating step, a member in which a content of Ni is 50% or more and 100% or less in an atomic ratio is used as the target.

14. The method of manufacturing the far-infrared transmitting member according to claim 11, wherein, in the oxidation step, oxygen having an oxygen flow rate ratio of 10% or more and 75% or less in a total amount of gas in the second space is turned into plasma to form the oxygen plasma.
